(19) United States
(12) Patent Application Publication
(10) Pub. No.: US 2026/0044661 A1
(43) Pub. Date: Feb. 12, 2026

(54) CIRCUIT DESIGN IMPLEMENTATION FOR 3-DIMENSIONAL INTEGRATED CIRCUIT DEVICES

(71) Applicant: Xilinx, Inc., San Jose, CA (US)

(72) Inventors: Dinesh D. Gaitonde, Fremont, CA (US); Chirag Ravishankar, Erie, CO (US); Quinn Doud, Longmont, CO (US)

(73) Assignee: Xilinx, Inc., San Jose, CA (US)

(21) Appl. No.: 18/797,296

(22) Filed: Aug. 7, 2024

(51) Int. Cl. G06F 30/394

(52) U.S. Cl. CPC G06F 30/394

(57) ABSTRACT

Implementing a circuit design for an integrated circuit device having a plurality of dies where each die has a plurality of fabric sub-regions (FSRs) includes detecting an inter-FSR net of the circuit design. A source of the inter-FSR net and an anchor for the inter-FSR net are projected to a selected die of the plurality of dies resulting in a projected source and a projected anchor in the selected die. The inter-FSR net is replaced with a modified inter-FSR net coupling the projected source with the projected anchor in the selected die and a new intra-FSR net coupling the anchor with a load of the inter-FSR net. The circuit design including the modified inter-FSR net and the new intra-FSR net is routed.

### TECHNICAL FIELD

This disclosure relates to implementing circuit designs for 3-dimensional (3D) integrated circuit devices.

### BACKGROUND

As integrated circuit (IC) devices increase in size and complexity, so do the circuit designs created for implementation within such IC devices. This results in an increase in the time required for computer-based implementation tools to generate a feasible implementation of a circuit design for a given target IC device. Certain phases of the implementation flow such as routing are often particularly problematic.

Larger circuit designs tend to have reduced routability meaning that the task of generating a feasible routing solution for larger circuit designs is more difficult for the implementation tools to achieve than for smaller circuit designs given a particular target IC device. The increased difficulty may manifest in increased runtimes for the implementation tools, e.g., the router. In other cases, the increased difficulty may manifest in the router failing to generate a feasible routing solution altogether.

### SUMMARY

In one or more embodiments, a method includes, for a circuit design for an integrated circuit (IC) device having a plurality of dies wherein each die has a plurality of fabric sub-regions (FSRs), detecting an inter-FSR net of the circuit design. The method includes projecting a source of the inter-FSR net and an anchor for the inter-FSR net to a selected die of the plurality of dies resulting in a projected source and a projected anchor in the selected die. The method includes replacing the inter-FSR net with a modified inter-FSR net coupling the projected source with the projected anchor in the selected die and a new intra-FSR net coupling the anchor with a load of the inter-FSR net. It should be appreciated that the inter-FSR net may have a plurality of anchors that may be projected such that the modified inter-FSR net couples the projected source with each projected anchor as described hereinbelow in greater detail. The method includes routing the circuit design including the modified inter-FSR net and the new intra-FSR net.

In one or more embodiments, a system includes a hardware processor capable of executing operations. The operations include, for a circuit design for an IC device having a plurality of dies wherein each die has a plurality of FSRs, detecting an inter-FSR net of the circuit design. The operations include projecting a source of the inter-FSR net and an anchor for the inter-FSR net to a selected die of the plurality of dies resulting in a projected source and a projected anchor in the selected die. The operations include replacing the inter-FSR net with a modified inter-FSR net coupling the projected source with the projected anchor in the selected die and a new intra-FSR net coupling the anchor with a load of the inter-FSR net. The operations include routing the circuit design including the modified inter-FSR net and the new intra-FSR net.

In one or more embodiments, a computer program product includes a computer readable storage medium having program instructions embodied therewith. The program instructions are executable by computer hardware to cause the computer hardware to execute operations. The operations include, for a circuit design for an IC device having a plurality of dies wherein each die has a plurality of FSRs, detecting an inter-FSR net of the circuit design. The operations include projecting a source of the inter-FSR net and an anchor for the inter-FSR net to a selected die of the plurality of dies resulting in a projected source and a projected anchor in the selected die. The operations include replacing the inter-FSR net with a modified inter-FSR net coupling the projected source with the projected anchor in the selected die and a new intra-FSR net coupling the anchor with a load of the inter-FSR net. The operations include routing the circuit design including the modified inter-FSR net and the new intra-FSR net.

This Summary section is provided merely to introduce certain concepts and not to identify any key or essential features of the claimed subject matter. Other features of the inventive arrangements will be apparent from the accompanying drawings and from the following detailed description.

### BRIEF DESCRIPTION OF THE DRAWINGS

The inventive arrangements are illustrated by way of example in the accompanying drawings. The drawings, however, should not be construed to be limiting of the inventive arrangements to only the particular implementations shown. Various aspects and advantages will become apparent upon review of the following detailed description and upon reference to the drawings.

FIG. 1 illustrates an example of an integrated circuit (IC) device in accordance with one or more embodiments of the disclosed technology.

FIG. 2 illustrates a plurality of nets of a circuit design that have been placed for the IC device of FIG. 1 in accordance with one or more embodiments of the disclosed technology.

FIG. 3 illustrates a method of implementing a circuit design in accordance with one or more embodiments of the disclosed technology.

FIG. 4 illustrates certain operative features of the method of FIG. 3 in accordance with one or more embodiments of the disclosed technology.

FIG. 5 illustrates certain operative features of the method of FIG. 3 in accordance with one or more embodiments of the disclosed technology.

FIG. 6 illustrates certain operative features of the method of FIG. 3 in accordance with one or more embodiments of the disclosed technology.

FIG. 7 illustrates certain operative features of the method of FIG. 3 in accordance with one or more embodiments of the disclosed technology.

FIG. 8 illustrates certain operative features of the method of FIG. 3 in accordance with one or more embodiments of the disclosed technology.

FIG. 9 illustrates certain operative features of the method of FIG. 3 in accordance with one or more embodiments of the disclosed technology.

FIG. 10 illustrates certain operative features of the method of FIG. 3 in accordance with one or more embodiments of the disclosed technology.

FIG. 11 illustrates an example implementation of a data processing system for use with the inventive arrangements described herein.

### DETAILED DESCRIPTION

While the disclosure concludes with claims defining novel features, it is believed that the various features described within this disclosure will be better understood from a consideration of the description in conjunction with the drawings. The process(es), machine(s), manufacture(s) and any variations thereof described herein are provided for purposes of illustration. Specific structural and functional details described within this disclosure are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

This disclosure relates to implementing circuit designs for 3-dimensional (3D) integrated circuit (IC) devices. A 3D IC device refers to an IC device that is formed of a plurality of dies, also referred to as chiplets. The embodiments provide methods, systems, and computer program products capable of implementing and, more particularly, routing, circuit designs for implementation in 3D IC devices. The embodiments are capable of generating feasible routing solutions and doing so in less runtime than other conventional routing techniques.

As noted, circuit designs have grown in size in complexity resulting in an increase in the time required for computer-based implementation tools to generate a feasible implementation of a circuit design for a given target IC device. Conventional routing techniques are unable to scale with the large number of hardware cores available in many computer-based implementation tools. Such is the case as routing entails a negotiation between competing nets to use the same routing resources in the target IC device. Multiple cores and/or threads may not operate in parallel when each is attempting to utilize the same routing resources.

In accordance with the inventive arrangements, particular nets of the circuit design that are often responsible for a majority of the congestion encountered when routing the circuit design are detected. Congestion may be detected using any of a variety of known probabilistic congestion metrics that indicate routing demand and that, in general, are predictive of where in the target IC device a router will have difficulty routing a circuit design given a placement for that circuit design. In many cases, the type of nets responsible for a majority of the congestion do not change with the size of the circuit design. The percentage of total runtime devoted to routing these types of nets also remains relatively constant across different sizes of circuit designs.

For purposes of illustration, each die of the 3D IC device may be subdivided into a plurality of fabric sub-regions (FSRs). The nets responsible for the majority of the congestion are those that cross FSR boundaries and are referred to herein as inter-FSR nets. An inter-FSR net is a net having a source in a first FSR and one or more loads in one or more different FSRs than the source. Inter-FSR nets are distinguished from nets that do not cross FSR boundaries referred to herein as intra-FSR nets. An intra-FSR net is a net of the circuit design whose source and load(s) are placed in a same FSR or are within a same FSR of two or more stacked dies.

In one or more embodiments, an inter-FSR net may be transformed into a modified version of the inter-FSR net and one or more intra-FSR nets. The transformation may be performed by projecting certain features of the inter-FSR net such as the source and one or more anchors derived based on the load(s) of the inter-FSR net to a selected die of the 3D IC device. The modified version of the inter-FSR net couples the source as projected with the anchor(s) as projected and may be routed in the selected die. Each anchor of the original inter-FSR net, as placed in the original die(s) of the 3D IC device, may be routed to one or more loads of the original inter-FSR net as one or more intra-FSR nets. Routing of the original inter-FSR net may be completed by connecting the source with the projected source and each anchor with its projected anchor.

The transformation allows the inter-FSR nets, as modified, to be routed in parallel with the intra-FSR nets of the circuit design as the two types of nets do not compete for same routing resources of the 3D IC device. The many intra-FSR nets also may be routed in parallel. That is, the intra-FSR nets of different FSRs of the 3D IC device may be routed in parallel as such intra-FSR nets do not compete for same routing resources of the 3D IC device.

The embodiments described herein reduce the complexity of routing the circuit design. The routing task is effectively divided into a plurality of different routing sub-tasks based on the classification of nets and the transformation of nets as described. Each of the sub-tasks is less complex than the original routing task for the entire circuit design (e.g., in reference to all of the original nets). The reduced complexity translates into reduced router runtime to achieve a routing solution for the circuit design. The ability to parallelize the routing operations as described herein provides a further reduction in router runtime to achieve the routing solution for the circuit design. In one or more embodiments, the techniques described herein may be used in the context of emulation and/or prototyping of circuit designs using programmable ICs to reduce runtime of the implementation tools.

For purposes of simplicity and clarity of illustration, elements shown in the figures have not necessarily been drawn to scale. For example, the dimensions of some of the elements may be exaggerated relative to other elements for clarity. Further, where considered appropriate, reference numbers are repeated among the figures to indicate corresponding, analogous, or like features.

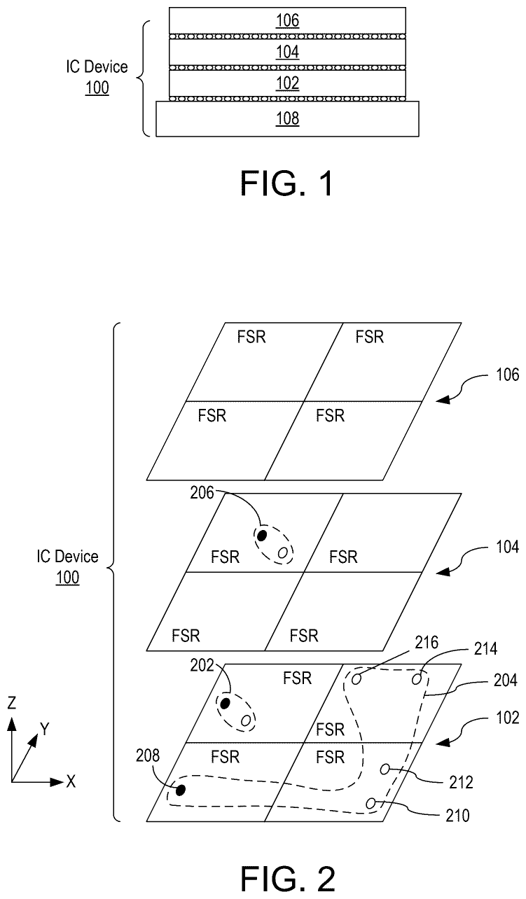

FIG. 1 illustrates an example of an IC device 100 in accordance with one or more embodiments of the disclosed technology. IC device 100 is an example of a 3D IC device. Within this disclosure, the term “3D IC device” or “multi-die IC” means an IC device implemented to include two or more dies coupled to one another and included within a single package. As illustrated, IC device 100 includes a plurality of dies 102, 104, and 106. In one or more embodiments, each of dies 102, 104, and 106 includes programmable circuitry. Programmable logic is an example of programmable circuitry.

In the example, dies 102, 104, and 106 are stacked. Dies 102, 104, and 106 may be coupled using solder bumps (e.g., micro-bumps). For purposes of illustration and not limitation, die 102 is coupled to a package substrate 108. Package substrate 108 provides the package with mechanical base support and provides an electrical interface for connecting to nodes external to the package. Die 102 may be coupled to package substrate 108 using solder bumps.

The example of FIG. 1 is provided for purposes of illustration only. It should be appreciated that other types of packaging technologies may be used. In one or more embodiments, two or more active dies may be stacked atop of an interposer.

The interposer may support multiple stacks of two or more active dies or various combinations of dies including at least one stack of two or more active dies. In one or more embodiments, IC device 100 is characterized by the inclusion and stacking of a plurality, e.g., two or more, active dies such as dies 102, 104, and 106. In some embodiments, IC device 100 may include more than three dies or only two dies. In the example of FIG. 1, dies 102, 104, and 106 may be implemented as identical dies or substantially identical dies. For example, certain nodes within die 102 may align with corresponding nodes in die 104. Similarly, certain nodes within die 104 may align with corresponding nodes in die 106.

In one or more embodiments, each of dies 102, 104, and 106 may be implemented as a same or substantially same programmable die such as a Field Programmable Gate Array (FPGA). Accordingly, the stacking of dies 102, 104, and 106 indicates that certain circuit structures such as interconnects or interconnect tiles of the respective dies are aligned in the Z-axis. This allows each such interconnect or interconnect tile to communicate in the X-axis and/or Y-axis direction(s) with other tiles and/or components in the same die as well as with other tiles and/or components directly above and/or below as aligned in the Z-axis in other dies if such dies are available in the IC device.

The use of same dies and vertically aligning the dies allows connections between dies 102 and 104, dies 104 and 106, and/or dies 102 and 106 to be created using conductive structures such as through vias (TVs). TVs may be implemented as through silicon vias (TSVs), through glass vias (TGVs), or other via structures depending upon the particular materials used to implement dies 102, 104, 106 and/or package substrate 108. As generally known, TVs are vias that form an electrical connection that transverses, e.g., extends through a substantial portion, if not the entirety of, the process layers of a die and/or package substrate. The TVs are typically perpendicular to the process layers. TVs, like wires and vias, may be formed of any of a variety of different conductive materials including, but not limited to, copper, aluminum, gold, nickel, various silicides, and/or other suitable materials.

In one or more embodiments, a selected die of IC device 100 is reserved, in whole or in part, for use in routing inter-FSR nets. In one or more embodiments, the selected die is reserved in whole such that no components of the circuit design are placed in the selected die. In one or more other embodiments, the selected die is reserved in part such that a limited number of components of the circuit design may be placed in the selected die. The die is otherwise, however, reserved for implementing inter-FSR nets.

For example, die 106 may be the selected die that is reserved, in whole or in part, for use in routing inter-FSR nets. Dies 102 and 104 are available to have components of the circuit design placed therein. Appreciably, more than one die may be reserved in whole or in part for routing inter-FSR nets so long as at least one die of the 3D IC device is available for receiving, e.g., placing, components of the circuit design being implemented.

FIG. 2 illustrates a plurality of nets of a circuit design that have been placed for IC device 100 in accordance with one or more embodiments of the disclosed technology. In the example of FIG. 2, dies 102 and 104 are available for placing a circuit design. Die 106 is reserved for use in routing inter-FSR nets. For purposes of illustration, the circuit design has been placed such that components of the circuit design are placed in dies 102 and 104. The placer is restricted in this example from placing any components of the circuit design in die 106.

In the example of FIG. 2, each die 102, 104, and 106 is subdivided into a plurality of FSRs. For purposes of illustration, each die is subdivided into 4 FSRs. The number of FSRs and configuration of FSRs may be different from that illustrated. Each FSR defines a region (e.g., a portion or sub-region) of a die. FSRs may be defined to be the same in terms of shape and size (e.g., uniform). In other cases, FSRs may not be uniform (e.g., differ in terms of shape and/or size).

In the example of FIG. 2, the FSRs of each die are shown to align. This need not be the case. While FSRs may be uniform in some cases, FSRs may be different or non-uniform in other cases. That is, the number of FSRs in each die, the size of each FSR, and/or the shape of each FSR may differ. Further, the number of FSRs, size(s) of FSRs, and/or shape(s) of FSRs may be adjusted or modified by the implementation tools as discussed hereinbelow.

In one or more embodiments, the implementation tools may adjust, e.g., change or modify, the number, size, and/or shape of FSRs based on the circuit design itself. For example, in some cases, FSRs may be defined as a region that includes a plurality of configurable logic blocks (CLBs), while in other cases an FSR may include only a single CLB. As discussed, an intra-FSR net is a net that resides completely within an FSR. That is, the source (or driver) of the intra-FSR net and each load of the intra-FSR net is located in a same FSR of IC device 100. Accordingly, it may be observed that changing the number, size, and/or shape of one or more FSRs will affect whether nets, as placed, are considered classified by the implementation tools as inter-FSR nets or intra-FSR nets. By modifying the FSRs, the implementation tools are capable of adjusting number of inter-FSR nets and number of intra-FSR nets of the circuit design to control routing runtime.

Referring to the example of FIG. 2, die 102 includes an intra-FSR net 202 and an inter-FSR net 204. Die 104 includes an intra-FSR net 206. As illustrated, intra-FSR net 202 resides completely within the upper left FSR of die 102. Intra-FSR net 206 resides completely within the upper left FSR of die 104. Though not illustrated, intra-FSR nets may span more than one die, but have the source and all loads of the intra-FSR net in the same FSR of two or more different dies. For example, intra-FSR net 206 may have the source located as shown in FIG. 2 (e.g., the upper left FSR of die 104) with the load located in the same FSR (e.g., the upper-left FSR) albeit in die 102. FSRs that are aligned in the Z-axis are considered the “same FSR in different dies” within this disclosure. Inter-FSR net 204 includes a source 208 and loads 210, 212, 214, and 216. Inter-FSR net 204 spans a plurality of FSRs in that the source is located in a different FSR than one or more of the loads. For purposes of illustration, the source of an inter-FSR net may be referred to herein from time-to-time as an “inter-FSR source” and the load of an inter-FSR net may be referred to herein from time-to-time as an “inter-FSR load.”

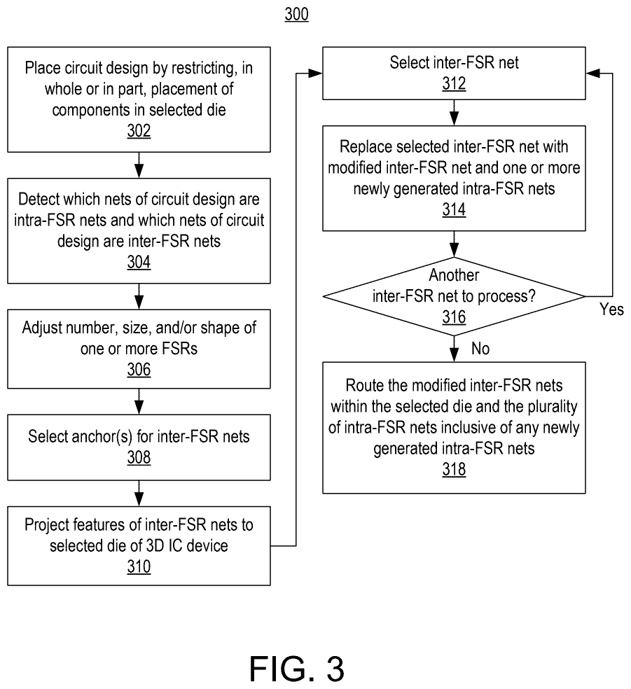

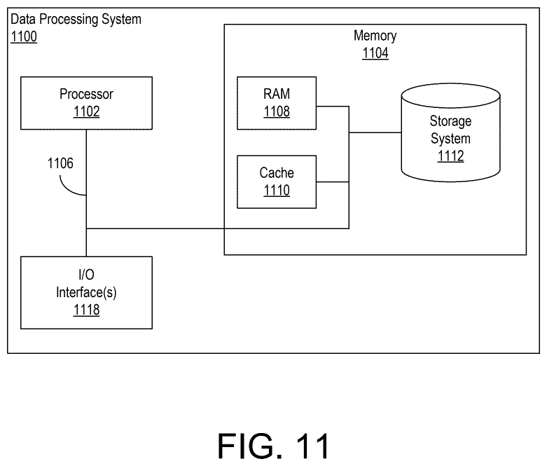

FIG. 3 illustrates a method 300 of implementing a circuit design in accordance with one or more embodiments of the disclosed technology. The operations described in connection with FIG. 3 may be performed by a data processing system executing suitable computer-readable program instructions. For example, the data processing system may execute program code that is capable of performing an implementation flow that may include synthesis, placement, routing, and/or generation of configuration data that, may be loaded into an IC device such as IC device 100 to physically realize the circuit design as placed and routed therein. For example, the program code may be embodied as, or included in, an Electronic Design Automation (EDA) tool that is executed by the data processing system. An example of a data processing system (system) that is capable of performing the operations described within this disclosure is described in connection with FIG. 11.

Method 300 may begin in a state where a circuit design, e.g., a user circuit design, is undergoing processing through an implementation flow for a target 3D IC device such as IC device 100. Referring to FIGS. 2 and 3, in block 302, the system is capable of placing the circuit design. The system is capable of placing the circuit design by restricting, in whole or in part (e.g., based on settings or preferences of the implementation tool), placement of components in the selected die. In this example, the selected die is die 106. Accordingly, the system places, or assigns, the components of the circuit design to locations or sites of or in dies 102 and 104 only of IC device 100. Thus, die 106 has no components of the circuit design located or assigned therein.

It should be appreciated that the selected die may be a different die than die 106. For example, the selected die may be die 102 (e.g., the lowest die as opposed to the top or highest die). In another example, the selected die may be a middle die such as die 104. As noted, there may be more than one selected die reserved for inter-FSR routing.

In one or more embodiments, the system is capable of making a copy of the circuit design (e.g., the netlist) that includes the placed components. The operations performed in connection with routing the circuit design may be performed on the copy of the circuit design including the placement information.

In block 304, the system is capable of detecting which nets of the circuit design are intra-FSR nets and which nets of the circuit design are inter-FSR nets. For example, the system is capable of parsing the circuit design to detect which of the nets cross or traverse an FSR boundary as described (e.g., have a source in one FSR and at least one load in another FSR) and which do not based on the placement. Referring to FIG. 2, for example, the system detects or classifies nets 202 and 206 as intra-FSR nets and detects or classifies net 204 as an inter-FSR net.

In block 306, the system optionally adjusts at least one of a number of FSRs, adjusts a size of one or more FSRs, and/or adjusts a shape of one or more FSRs. The FSRs may be set using a default layout or tiling. Thereafter, the system may adjust one or more FSRs as described herein. In general, adjusting one or more FSRs can reduce the runtime of the implementation tools in performing routing.

In one or more embodiments, the system uses one or more heuristics such as a known probabilistic congestion metric to estimate those FSRs of with highest expected congestion. Such FSRs may be those with at least a minimum number of inter-FSR nets crossing a boundary of the FSR(s) or the top N FSRs having the largest number of inter-FSR nets that cross a boundary of the FSR(S), where N is an integer value. In one or more other embodiments, the system may use a net count, a pin count, the number of intra-FSR nets, the number of inter-FSR nets, or any combination of the heuristics described herein as a basis for adjusting one or more FSRs.

By adjusting one or more FSRs, congestion may be alleviated. For example, the system may change the boundary of an FSR (e.g., adjusting the size and/or shape) and/or merge two or more FSRs (e.g., adjust the number of FSRs) and/or split two or more FSRs (e.g., adjust the number of FSRs) to reduce congestion. Appreciably, changing the boundary of an FSR may cause an inter-FSR net to be completely subsumed or encompassed by an FSR thereby changing that inter-FSR net to an intra-FSR net. The reverse may also be true. In one or more embodiments, the system adjusts one or more FSRs to reduce the load count of inter-FSR nets.

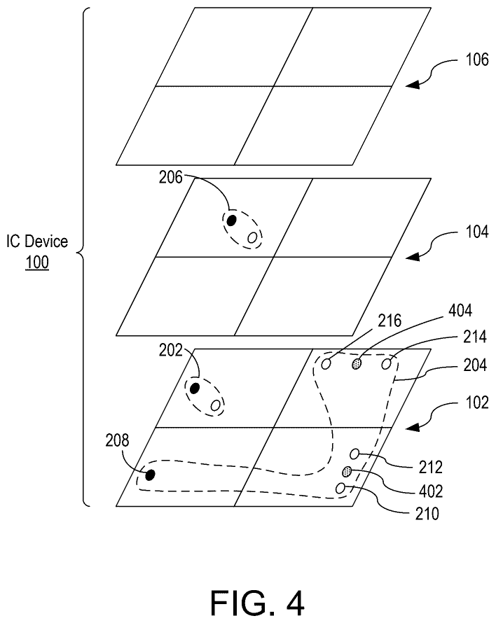

In block 308, the system selects anchor(s) for the inter-FSR nets. Referring to FIG. 4, the system has selected anchors 402 and 404 for inter-FSR net 204. In general, for each different FSR that includes one or more loads of an inter-FSR net, one or more anchors may be selected. In the example, anchor 402 is selected for inter-FSR loads 210 and 212 located in the lower right FSR of die 102 and anchor 404 is selected for inter-FSR loads 214 and 216 in the upper right FSR of die 102. The anchor is a particular circuit component or pin thereof (e.g., a lookup-table or flip-flop) that is capable of operating as a driver to drive the leaf nodes, i.e., loads, of an inter-FSR net located in the same FSR as the anchor. In the example of FIG. 4, anchor 402 may drive loads 210 and 212 of inter-FSR net 204. Similarly, anchor 404 may drive loads 214 and 216 of inter-FSR net 204.

Anchors may be selected using any of a variety of different techniques. In one or more embodiments, anchors may be selected as component or component pin closest to a centroid of two or more loads in a same FSR. For example, anchor 402 may be a pin or component within die 102 that is closest to, or located at, a centroid of loads 210 and 212. In another example, the anchors may be selected as the pin or component closest to a location that minimizes wire length to connect the anchor to each load driven by that anchor. For example, anchor 402 may be a pin or component within die 102 that is closest to a location that minimizes the wire length when routing from anchor 402 to each of loads 210 and 212. The inventive arrangements are not intended to be limited by the particular technique used to select the anchors. In some cases, for example, more than one anchor may be selected in a single FSR for a single inter-FSR net.

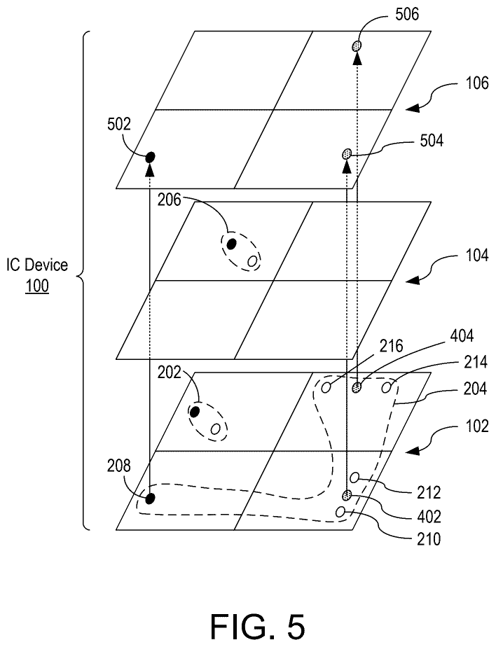

In block 310, the system projects features of the inter-FSR nets to the selected die of IC device 100. Referring to FIG. 5, the system projects source 208 and each anchor, e.g., anchors 402 and 404, to the selected die which is die 106 in this example. The projection effectively translates the location of each feature, as placed, to the same location albeit in the selected die. FIG. 5 illustrates that source 208 is projected into die 106 as projected source 502. As illustrated, with dies 102, 104, and 106 being the same and stacked in vertical alignment, source 208 is located in the lower left FSR and projected source 502 is located in the lower left FSR albeit in die 106 vertically aligned with source 208. That is source 208 and projected source 502 are located in the same relative FSR and, within each respective FSR, at the same relative location (e.g., the same relative pin or component). The particular component or site specified by source 208 and projected source 502 are the same, albeit in different dies. In one or more other embodiments in which dies may vary, the system may perform a mapping of a connection made from a location in one die to a location in the other die when such locations are not vertically aligned.

Similarly, anchor 402 is projected into die 106 as projected anchor 504, and anchor 404 is projected into die 106 as projected anchor 506. Anchor 402 is located in the lower right FSR and projected anchor 504 is located in the lower right FSR albeit in die 106 vertically aligned with anchor 402. That is anchor 402 and projected anchor 504 are located in the same relative FSR and, within each respective FSR, at the same relative location (e.g., the same relative pin or component). The particular component or site specified by anchor 402 and projected anchor 504 are the same, albeit in different dies. The same is true of anchor 404 and projected anchor 506.

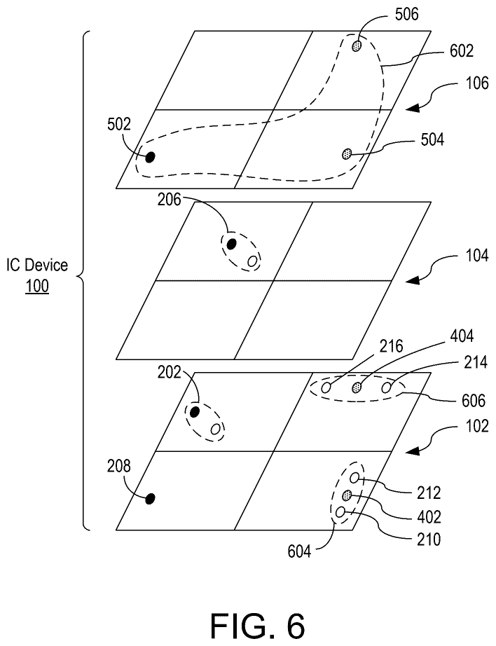

In block 312, the system selects an inter-FSR net to be processed. For purposes of illustration, the system selects inter-FSR net 204 for processing. In block 314, the system performs a transformation of the selected inter-FSR net by replacing the selected inter-FSR net with a modified inter-FSR net and one or more newly generated intra-FSR nets. Referring to FIG. 6, the system is capable of generating a modified version of the original inter-FSR net, which is inter-FSR net 204 in this example, as modified inter-FSR net 602. Modified inter-FSR net 602 is formed using projected source 502 as the source and each projected anchor 504, 506 for inter-FSR net 204 as a load of modified inter-FSR net 602. Modified inter-FSR net 602 is located in the selected die. Each newly created intra-FSR net that is created for inter-FSR net 204 is generated based on, or using, an anchor of inter-FSR net 204. For example, anchor 402 is used as a source of newly created (e.g., new) intra-FSR net 604. New intra-FSR net 604 couples anchor 402 with loads 210 and 212. Whereas loads 210 and 212 were loads of inter-FSR net 204, loads 210 and 212 are now loads of new intra-FSR net 604. Similarly, anchor 404 is used as a source of a new intra-FSR net 606 that is generated by the system with loads 214 and 216 of inter-FSR net 204 now becoming loads of the new intra-FSR net 606.

In block 316, the system determines whether there is another inter-FSR net to process. In response to determining that one or more inter-FSR nets of the circuit design remain to be processed, method 300 loops back to block 312 to select another inter-FSR net for processing through the transformation operation. In response to determining that there are no further inter-FSR nets of the circuit design to process, method 300 continues to block 318. In the examples presented, for purposes of illustration, only one inter-FSR net is illustrated. It should be appreciated that a typical circuit design will include many inter-FSR nets.

In block 318, the system is capable of routing the circuit design. For example, the system routes the modified inter-FSR nets within the selected die and routes the plurality of intra-FSR nets, inclusive of any newly generated or new intra-FSR nets created in block 314. In performing the routing operation, the system is further capable of routing each source to each corresponding projected source and routing each anchor to each corresponding projected anchor.

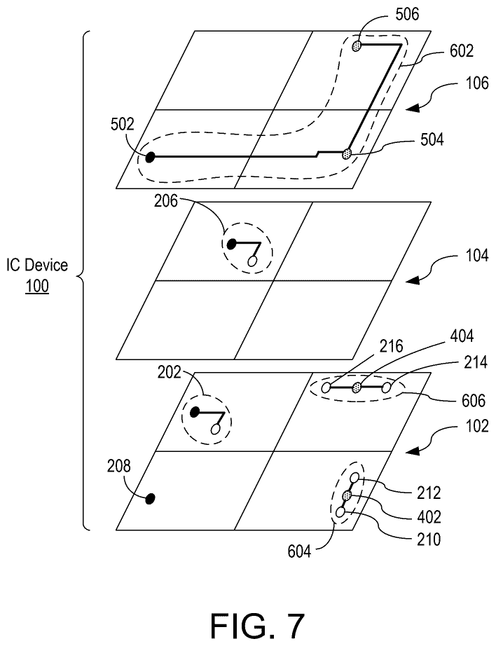

Referring to FIG. 7, the system routes modified inter-FSR net 602 and also routes intra-FSR nets 202 and 206 and new intra-FSR nets 604 and 606. The system routes the respective nets by designating particular routing resources (e.g., conductive elements or wires of the 3D IC device) to make connections or couple elements of the nets. Because die 106 was reserved during the placement process, die 106 includes no components belonging to intra-FSR nets. As may be seen in the example of FIG. 7, modified inter-FSR net 602, being implemented and routed in die 106, does not utilize any of the same routing resources that would be used to route any intra-FSR net. The only components included in die 106, in the example of FIG. 7, are projected source(s) and projected anchor(s) corresponding specifically to inter-FSR nets (e.g., modified versions thereof). The routing of modified inter-FSR nets and intra-FSR nets utilize completely different and distinct routing resources. Further, it may be observed that because each of dies 102 and 104 now includes only intra-FSR nets, the intra-FSR nets within different FSRs do not compete for the same routing resources. For example, intra-FSR net 206 may be routed concurrently with intra-FSR net 202, intra-FSR net 604, and/or intra-FSR net 606 as each net will use only routing resources located in the particular FSR in which the intra-FSR net is located.

As noted, the routing process also includes establishing connections between certain nodes located in different dies using inter-die connections. For example, each source of an original inter-FSR net is connected with the projected inter-FSR source for that net (e.g., the corresponding projected source) using an inter-die connection. Similarly, each anchor of the original inter-FSR net is connected to the projected anchor for that anchor of the net (e.g., the corresponding anchor) using an inter-die connection.

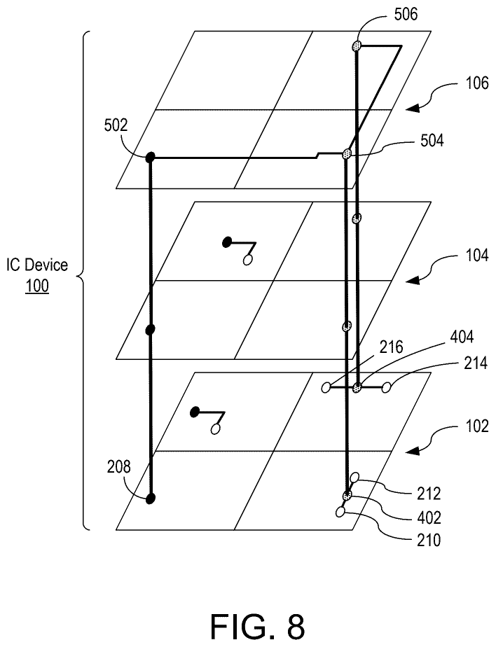

In the example of FIG. 8, source 208 is routed, e.g., coupled, to projected source 502 by an inter-die connection. Anchor 402 is routed, e.g., coupled, to projected anchor 504 using an inter-die connection. Further, anchor point 404 is routed, e.g., coupled, to projected anchor 506 using an inter-die connection. The inter-die connections used may include wires and/or conductive circuit structures that establish electrical connections between and/or among dies. The inter-die connections, illustrated as the vertical lines in the example of FIG. 8, may be implemented using TVs and/or vias within dies and utilize solder bumps or other conductive circuit structures that couple dies or are disposed between dies.

The foregoing operations enable parallelism in the routing task. In particular, the system is capable of routing modified inter-FSR nets concurrently, or in parallel, with intra-FSR nets. This may be accomplished by handling inter-FSR nets in a first thread and/or in a first core of a hardware processor while handling intra-FSR nets in one or more second and different thread(s) and/or in one or more second and different core(s) of the hardware processor. The system is also capable of routing intra-FSR nets of different FSRs in parallel. For example, each FSR may be allocated to a different thread and/or a different core of a hardware processor such that intra-FSR nets of different FSRs (e.g., two or more different FSRs) may be routed in parallel. If, for example, the system supports tens or hundreds of threads or cores, the system may allocate each such thread or core a different FSR for routing of the intra-FSR nets therein. The inter-FSR nets, among themselves, may be routed using a single core or thread using conventional techniques since such nets compete for same routing resources. Similarly, the intra-FSR nets within a same FSR, among themselves, may be routed using a single core or thread using conventional techniques since such nets compete for same routing resources.

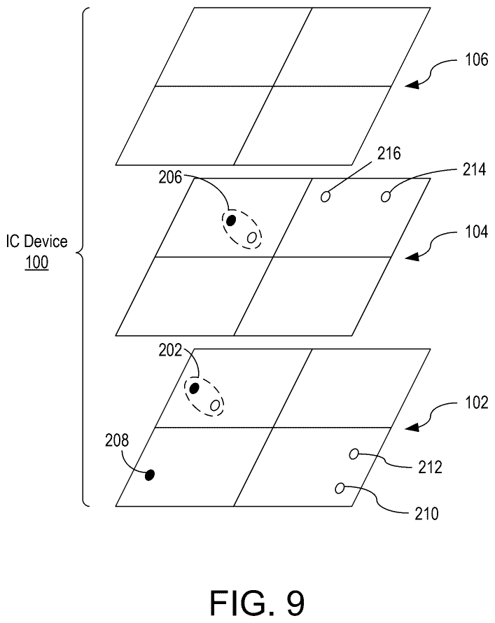

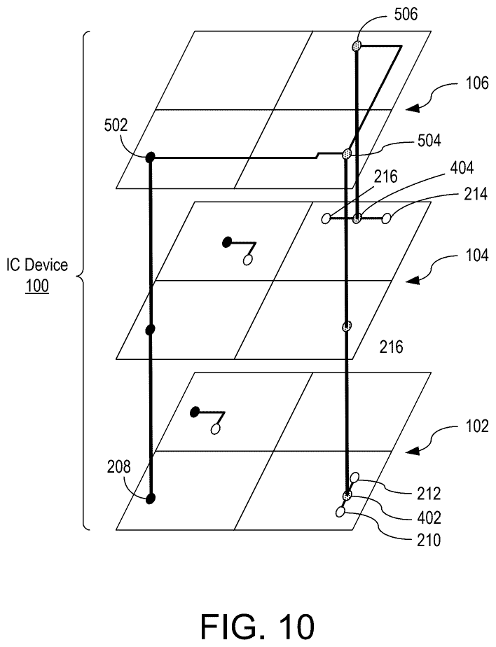

The examples described herein illustrate the case of an inter-FSR net that is disposed within a single die. In one or more other embodiments, the routing techniques described herein may be implemented in cases where an inter-FSR net spans two or more dies. FIG. 9 illustrates an example in which the inter-FSR net spans two dies. In the example of FIG. 9, the inter-FSR net 206 spans dies 102 and 104. As shown, source 208, load 210, and load 212 are disposed in die 102. Load 214 and load 216 are disposed in die 104. The selection of anchors may be performed as previously described. The anchor for load 210 and load 212 will be in the same FSR as the loads. Similarly, the anchor for load 214 and load 216 will be in the same FSR as these two loads. Projection may be performed by the system in the same manner as described. The routing also may be performed as described. FIG. 10 illustrates a routed version of the example of FIG. 9. As shown, while intra-FSR net 402 is disposed and implemented in die 102, intra-FSR net 606 is disposed and routed in die 104.

In one or more embodiments, the system is capable of generating configuration data specifying the placed and routed circuit design for implementation in a target 3D IC device. The configuration data may be and/or include a configuration bitstream, program code, state setting data, or the like. The configuration data, upon loading into the 3D IC device, physically realizes the circuit design in the 3D IC device.

The particular order of operations shown in FIG. 3 is for purposes of illustration and not limitation. It should be appreciated that some operations may be performed in a different order than shown. Further, while some operations were described in connection with a particular net, it should be appreciated that such operations may be performed on iteratively for each of a plurality of nets of the circuit design.

FIG. 11 illustrates an example implementation of a data processing system 1100. As defined herein, the term “data processing system” means one or more hardware systems configured to process data, each hardware system including at least one processor and memory, wherein the processor is programmed with computer-readable program instructions that, upon execution, initiate operations. Data processing system 1100 can include a processor 1102, a memory 1104, and a bus 1106 that couples various system components including memory 1104 to processor 1102.

Processor 1102 may be implemented as one or more processors. In an example, processor 1102 is implemented as a hardware processor such as a central processing unit (CPU). Processor 1102 may be implemented as one or more circuits capable of carrying out instructions contained in program code. The circuit(s) may be an IC or embedded in an IC. Processor 1102 may be implemented using a complex instruction set computer architecture (CISC), a reduced instruction set computer architecture (RISC), a vector processing architecture, or other known architectures. Example processors include, but are not limited to, processors having an x86 type of architecture (IA-32, IA-64, etc.), Power Architecture, ARM processors, and the like.

Bus 1106 represents one or more of any of a variety of communication bus structures. By way of example, and not limitation, bus 1106 may be implemented as a Peripheral Component Interconnect Express (PCIe) bus. Data processing system 1100 typically includes a variety of computer system readable media. Such media may include computer-readable volatile and non-volatile media and computer-readable removable and non-removable media.

Memory 1104 can include computer-readable media in the form of volatile memory, such as random-access memory (RAM) 1108 and/or cache memory 1110. Data processing system 1100 also can include other removable/non-removable, volatile/non-volatile computer storage media. By way of example, storage system 1112 can be provided for reading from and writing to a non-removable, non-volatile magnetic and/or solid-state media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 1106 by one or more data media interfaces. Memory 1104 is an example of at least one computer program product.

Memory 1104 is capable of storing computer-readable program instructions that are executable by processor 1102. For example, the computer-readable program instructions can include an operating system, one or more application programs, other program code, and program data. Processor 1102, in executing the computer-readable program instructions, is capable of performing the various operations described herein that are attributable to a computer. In one or more examples, the compute-readable program instructions may include EDA tool, e.g., program code, capable of performing an implementation flow on a circuit design (e.g., synthesis, placement, routing, and/or configuration data/bitstream generation).

It should be appreciated that data items used, generated, and/or operated upon by data processing system 1100 are functional data structures that impart functionality when employed by data processing system 1100. As defined within this disclosure, the term “data structure” means a physical implementation of a data model's organization of data within a physical memory. As such, a data structure is formed of specific electrical or magnetic structural elements in a memory. A data structure imposes physical organization on the data stored in the memory as used by an application program executed using a processor.

Data processing system 1100 may include one or more Input/Output (I/O) interfaces 1118 communicatively linked to bus 1106. I/O interface(s) 1118 allow data processing system 1100 to communicate with one or more external devices and/or communicate over one or more networks such as a local area network (LAN), a wide area network (WAN), and/or a public network (e.g., the Internet). Examples of I/O interfaces 1118 may include, but are not limited to, network cards, modems, network adapters, hardware controllers, etc. Examples of external devices also may include devices that allow a user to interact with data processing system 1100 (e.g., a display, a keyboard, and/or a pointing device) and/or other devices such as accelerator card.

Data processing system 1100 is only one example implementation. Data processing system 1100 can be practiced as a standalone device (e.g., as a user computing device or a server, as a bare metal server), in a cluster (e.g., two or more interconnected computers), or in a distributed cloud computing environment (e.g., as a cloud computing node) where tasks are performed by remote processing devices that are linked through a communications network. In a distributed cloud computing environment, program modules may be located in both local and remote computer system storage media including memory storage devices.

The example of FIG. 11 is not intended to suggest any limitation as to the scope of use or functionality of example implementations described herein. Data processing system 1100 is an example of computer hardware that is capable of performing the various operations described within this disclosure. In this regard, data processing system 1100 may include fewer components than shown or additional components not illustrated in FIG. 11 depending upon the particular type of device and/or system that is implemented. The particular operating system and/or application(s) included may vary according to device and/or system type as may the types of I/O devices included. Further, one or more of the illustrative components may be incorporated into, or otherwise form a portion of, another component. For example, a processor may include at least some memory.

As defined herein, the singular forms “a,” “an,” and “the” are intended to include the plural forms as well, unless the context clearly indicates otherwise.

As defined herein, the terms “at least one,” “one or more,” and “and/or,” are open-ended expressions that are both conjunctive and disjunctive in operation unless explicitly stated otherwise. For example, each of the expressions “at least one of A, B, and C,” “at least one of A, B, or C,” “one or more of A, B, and C,” “one or more of A, B, or C,” and “A, B, and/or C” means A alone, B alone, C alone, A and B together, A and C together, B and C together, or A, B and C together.

As defined herein, the term “automatically” means without human intervention. As defined herein, the term “user”means a human being.

As defined herein, the term “computer-readable storage medium” means a storage medium that contains or stores program instructions for use by or in connection with an instruction execution system, apparatus, or device. As defined herein, a “computer-readable storage medium” is not a transitory, propagating signal per se. The various forms of memory, as described herein, are examples of computer-readable storage media. A non-exhaustive list of examples of computer-readable storage media include an electronic storage device, a magnetic storage device, an optical storage device, an electromagnetic storage device, a semiconductor storage device, or any suitable combination of the foregoing. A non-exhaustive list of more specific examples of a computer-readable storage medium may include: a portable computer diskette, a hard disk, a RAM, a read-only memory (ROM), an erasable programmable read-only memory (EPROM or Flash memory), an electronically erasable programmable read-only memory (EEPROM), a static random-access memory (SRAM), a portable compact disc read-only memory (CD-ROM), a digital versatile disk (DVD), a memory stick, or a floppy disk.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]”depending on the context.

As defined herein, the term “responsive to” and similar language as described above, e.g., “if,” “when,” or “upon,” means responding or reacting readily to an action or event. The response or reaction is performed automatically. Thus, if a second action is performed “responsive to” a first action, there is a causal relationship between an occurrence of the first action and an occurrence of the second action. The term “responsive to”indicates the causal relationship.

As defined herein, the term “substantially” means that the recited characteristic, parameter, or value need not be achieved exactly, but that deviations or variations, including for example, tolerances, measurement error, measurement accuracy limitations, and other factors known to those of skill in the art, may occur in amounts that do not preclude the effect the characteristic was intended to provide.

The terms first, second, etc. may be used herein to describe various elements. These elements should not be limited by these terms, as these terms are only used to distinguish one element from another unless stated otherwise or the context clearly indicates otherwise.

A computer program product may include a computer-readable storage medium or mediums having computer-readable program instructions thereon for causing a processor to carry out aspects of the inventive arrangements described herein. Within this disclosure, the term “program code,” “program instructions,” and “computer-readable program instructions” are used interchangeably. Computer-readable program instructions described herein may be downloaded to respective computing/processing devices from a computer-readable storage medium or to an external computer or external storage device via a network, for example, the Internet, a LAN, a WAN and/or a wireless network. The network may include copper transmission cables, optical transmission fibers, wireless transmission, routers, firewalls, switches, gateway computers and/or edge devices including edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations for the inventive arrangements described herein may be assembler instructions, instruction-set-architecture (ISA) instructions, machine instructions, machine dependent instructions, microcode, firmware instructions, or either source code or object code written in any combination of one or more programming languages, including an object-oriented programming language and/or procedural programming languages.

Computer-readable program instructions may include state-setting data. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some cases, electronic circuitry including, for example, programmable logic circuitry, an FPGA, or a PLA may execute the computer-readable program instructions by utilizing state information of the computer-readable program instructions to personalize the electronic circuitry, in order to perform aspects of the inventive arrangements described herein (e.g., implementing a circuit design as placed and routed).

Certain aspects of the inventive arrangements are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, may be implemented by computer-readable program instructions, e.g., program code.

These computer-readable program instructions may be provided to a processor of a computer, special-purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the operations specified in the flowchart and/or block diagram block or blocks.

The computer-readable program instructions may also be loaded onto a computer, other programmable data processing apparatus, or other device to cause a series of operations to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various aspects of the inventive arrangements. In this regard, each block in the flowchart or block diagrams may represent a module, segment, or portion of instructions, which comprises one or more executable instructions for implementing the specified operations.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order while in still other examples, one or more blocks may be performed in varying order with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and computer instructions.

What is claimed is:

1. A method, comprising:
for a circuit design for an integrated circuit device having a plurality of dies wherein each die has a plurality of fabric sub-regions (FSRs), detecting an inter-FSR net of the circuit design;
projecting a source of the inter-FSR net and an anchor for the inter-FSR net to a selected die of the plurality of dies resulting in a projected source and a projected anchor in the selected die;
replacing the inter-FSR net with a modified inter-FSR net coupling the projected source with the projected anchor in the selected die and a new intra-FSR net coupling the anchor with a load of the inter-FSR net; and
routing the circuit design including the modified inter-FSR net and the new intra-FSR net.

2. The method of claim 1, wherein the modified inter-FSR net is routed in the selected die.

3. The method of claim 1, wherein the routing routes intra-FSR nets of the circuit design of two or more different FSRs of the integrated circuit device in parallel.

4. The method of claim 1, wherein the modified inter-FSR net is routed within the selected die in parallel with intra-FSR nets of the circuit design inclusive of the new intra-FSR net.

5. The method of claim 1, further comprising:
placing the circuit design by restricting placement of components of the circuit design in the selected die.

6. The method of claim 1, further comprising:
adjusting at least one of a number of the FSRs, a size of one or more of the FSRs, or a shape of one or more of the FSRs.

7. The method of claim 1, further comprising:
selecting the anchor for the load of the inter-FSR net.

8. The method of claim 1, wherein the source and the load of the inter-FSR net are disposed in a same die of the plurality of dies.

9. The method of claim 1, wherein the source and the load of the inter-FSR net are disposed in different dies of the plurality of dies.

10. The method of claim 1, wherein the modified inter-FSR net is routed by coupling the source with the projected source and the anchor with the projected anchor using inter-die connections.

11. A system, comprising:
a hardware processor capable of executing operations including:
for a circuit design for an integrated circuit device having a plurality of dies wherein each die has a plurality of fabric sub-regions (FSRs), detecting an inter-FSR net of the circuit design;
projecting a source of the inter-FSR net and an anchor for the inter-FSR net to a selected die of the plurality of dies resulting in a projected source and a projected anchor in the selected die;
replacing the inter-FSR net with a modified inter-FSR net coupling the projected source with the projected anchor in the selected die and a new intra-FSR net coupling the anchor with a load of the inter-FSR net; and
routing the circuit design including the modified inter-FSR net and the new intra-FSR net.

12. The system of claim 11, wherein the modified inter-FSR net is routed in the selected die.

13. The system of claim 11, wherein the routing routes intra-FSR nets of the circuit design of two or more different FSRs of the integrated circuit device in parallel.

14. The system of claim 11, wherein the modified inter-FSR net is routed within the selected die in parallel with intra-FSR nets of the circuit design inclusive of the new intra-FSR net.

15. The system of claim 11, wherein the hardware processor is capable of executing operations comprising:
placing the circuit design by restricting placement of components of the circuit design in the selected die.

16. The system of claim 11, wherein the hardware processor is capable of executing operations comprising:
adjusting at least one of a number of the FSRs, a size of one or more of the FSRs, or a shape of one or more of the FSRs.

17. The system of claim 11, wherein the hardware processor is capable of executing operations comprising:
selecting the anchor for the load of the inter-FSR net.

18. The system of claim 11, wherein the source and the load of the inter-FSR net are disposed in a same die of the plurality of dies or are disposed in different dies of the plurality of dies.

19. The system of claim 11, wherein the modified inter-FSR net is routed by coupling the source with the projected source and the anchor with the projected anchor using inter-die connections.

20. A computer program product comprising one or more computer readable storage mediums having program instructions embodied therewith, wherein the program instructions are executable by computer hardware to cause the computer hardware to initiate executable operations comprising:
for a circuit design for an integrated circuit device having a plurality of dies wherein each die has a plurality of fabric sub-regions (FSRs), detecting an inter-FSR net of the circuit design;
projecting a source of the inter-FSR net and an anchor for the inter-FSR net to a selected die of the plurality of dies resulting in a projected source and a projected anchor in the selected die;
replacing the inter-FSR net with a modified inter-FSR net coupling the projected source with the projected anchor in the selected die and a new intra-FSR net coupling the anchor with a load of the inter-FSR net; and
routing the circuit design including the modified inter-FSR net and the new intra-FSR net.
